(19) United States
(12) Patent Application Publication
(10) Pub. No.: US 2025/0334883 A1
(43) Pub. Date: Oct. 30, 2025

(54) RESIST UNDERLAYER COMPOSITIONS, AND METHODS OF FORMING PATTERNS USING THE COMPOSITIONS

(71) Applicant: SAMSUNG SDI CO., LTD., Yongin-si (KR)

(72) Inventors: Sungwoo JUNG, Suwon-si (KR); Jihye LEE, Suwon-si (KR); Yoojeong CHOI, Suwon-si (KR); Seongjin KIM, Suwon-si (KR); Jaemin LEE, Suwon-si (KR); Jungin MUN, Suwon-si (KR); Hwayoung JIN, Suwon-si (KR)

(21) Appl. No.: 19/194,360

(22) Filed: Apr. 30, 2025

(30) Foreign Application Priority Data
Apr. 30, 2024 (KR) 10-2024-0058073

(51) Int. Cl. G03F 7/09; G03F 7/16; H01L 21/311; H01L 21/3213

(52) U.S. Cl. CPC G03F 7/094; G03F 7/168; H01L 21/31144; H01L 21/32139

(57) ABSTRACT

A resist underlayer composition, and a method of forming a photoresist pattern using the resist underlayer composition are provided. The resist underlayer composition includes a polymer including at least one of a structural unit represented by Chemical Formula 1, Chemical Formula 2, or Chemical Formula 3, a protected imidazole compound, and a solvent.

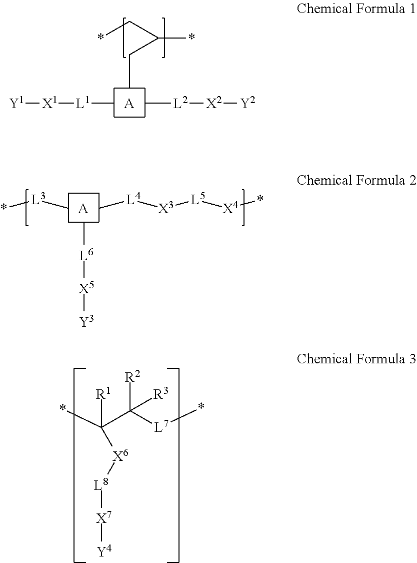

### CROSS-REFERENCE TO RELATED APPLICATION

This application claims priority to and the benefit of Korean Patent Application No. 10-2024-0058073 filed in the Korean Intellectual Property Office on Apr. 30, 2024, the entire disclosure of which is incorporated herein by reference.

### BACKGROUND

### 1. Field

Embodiments of this disclosure relate to resist underlayer compositions, and methods of forming patterns (e.g., photoresist patterns) using the same.

### 2. Description of the Related Art

Recently, the semiconductor industry has developed the utilization of ultra-fine techniques characterized by patterns that span a mere few nanometers to several tens of nanometers (e.g., having a pattern with dimensions of a few nanometers, to several tens of nanometers in size). The deployment of such precise methodologies necessitates the adoption of sophisticated photolithographic processes, which are integral to achieving the desired dimensional accuracy (i.e., the implementation of a suitable ultrafine technique essentially requires (or there is a desire for) effective lithographic techniques and processes capable of producing the proper dimensions).

A lithographic technique is a processing method that includes coating a photoresist film on a semiconductor substrate such as a silicon wafer to form a thin film, irradiating the photoresist film with activating radiation such as ultraviolet rays through a mask pattern on which the device pattern is drawn, developing the resultant to obtain a photoresist pattern, and etching the substrate using the photoresist pattern as a protective layer to form a fine pattern corresponding to the pattern, on the surface of the substrate.

As semiconductor patterns become increasingly finer, a thickness of the photoresist layer is desired or required to be thinner, and accordingly, a thickness of the resist underlayer is also desired or required to be thinner. The resist underlayer should not collapse the photoresist pattern even if (e.g., when) it is substantially thin, should have good adhesion to the photoresist, and should be formed to have a uniform (or substantially uniform) thickness. In some embodiments, the resist underlayer is desired or required to have a high refractive index and low extinction coefficient for the light used in photolithography and a faster etch rate than the photoresist layer.

### SUMMARY

One or more aspects of embodiments of the present disclosure are directed toward a resist underlayer composition that enhances or improves patterning performance and energy efficiency by enhancing or improving sensitivity to an exposure light source (e.g., even in a fine patterning process), and provides a resist underlayer having a uniform (or substantially uniform) pattern.

One or more aspects of embodiments of the present disclosure are directed toward a method of forming a pattern (e.g., photoresist pattern) using the resist underlayer composition.

Additional aspects of embodiments will be set forth in part in the description which follows and, in part, will be apparent from the description, or may be learned by practice of the presented embodiments of the disclosure.

A resist underlayer composition according to some example embodiments includes a polymer including at least one of (e.g., selected from among) a structural unit represented by Chemical Formula 1, a structural unit represented by Chemical Formula 2, and a structural unit represented by Chemical Formula 3, a protected imidazole compound, and a solvent:

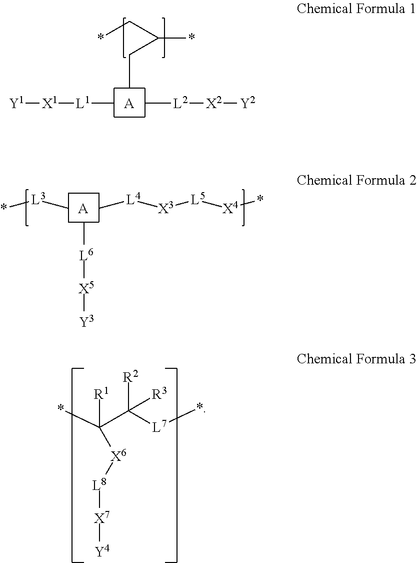

In Chemical Formula 1 to Chemical Formula 3,
A may be a heterocyclic group including a nitrogen atom in the ring (e.g., a ring-forming nitrogen atom),
L¹ to L⁸ may each independently be a single bond (e.g., a single covalent bond), a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a (e.g., any suitable) combination thereof,
X¹ to X⁷ may each independently be a single bond (e.g., a single covalent bond), —O—, —S—, —S(═O)—, —S(═O)₂—, —C(═O)—, —(C═O)O—, —O(C═O)O—, —NR^{a}— (wherein, R^{a} is hydrogen, deuterium, or a C1 to C10 alkyl group), or a (e.g., any suitable) combination thereof,
Y¹ and Y² may each independently be hydrogen, deuterium, a hydroxyl group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a (e.g., any suitable) combination thereof, provided at least one of (e.g., selected from among) Y¹ and Y² is an epoxy group,
Y³ and Y⁴ may each independently be an epoxy group,
R¹ to R³ may each independently be hydrogen, deuterium, or a substituted or unsubstituted C1 to C10 alkyl group, and
* is a linking point:

The protected imidazole compound may be represented by Chemical Formula 4:

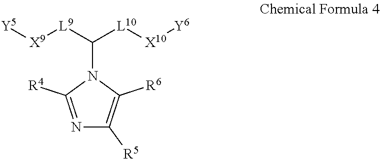

wherein, in Chemical Formula 4,
L⁹ and L¹⁰ may each independently be a single bond (e.g., a single covalent bond), a substituted or unsubstituted C1 to C20 alkylene group, or a substituted or unsubstituted C2 to C20 alkenylene group,
X⁹ and X¹⁰ may each independently be a single bond (e.g., a single covalent bond), —O—, —S—, —S(═O)—, —S(═O)₂—, —C(═O)—, —(C═O)O—, —O(C═O)O—, —NR^{b}— (wherein, R^{b} is hydrogen, deuterium, or a C1 to C10 alkyl group), or a (e.g., any suitable) combination thereof,
Y⁵ and Y⁶ may each independently be a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, or a (e.g., any suitable) combination thereof,
R⁴ to R⁶ may each independently be hydrogen, deuterium, a halogen atom, a hydroxyl group (—OH), a cyano group (—CN), a nitro group (—NO₂), sulfonic acid group (—SO₃H), —C(═O)R^{c} (wherein, R^{c} is hydrogen, deuterium, or a substituted or unsubstituted C1 to C10 alkyl group), —C(═O)OR^{d} (wherein, R^{d} is hydrogen, deuterium, or a substituted or unsubstituted C1 to C10 alkyl group), a substituted or unsubstituted C1 to C10 alkyl group, a substituted or unsubstituted C6 to C20 aryl group, or a (e.g., any suitable) combination thereof.

A of Chemical Formula 1 and Chemical Formula 2 may be represented by any one of Chemical Formula A-1 to Chemical Formula A-4.

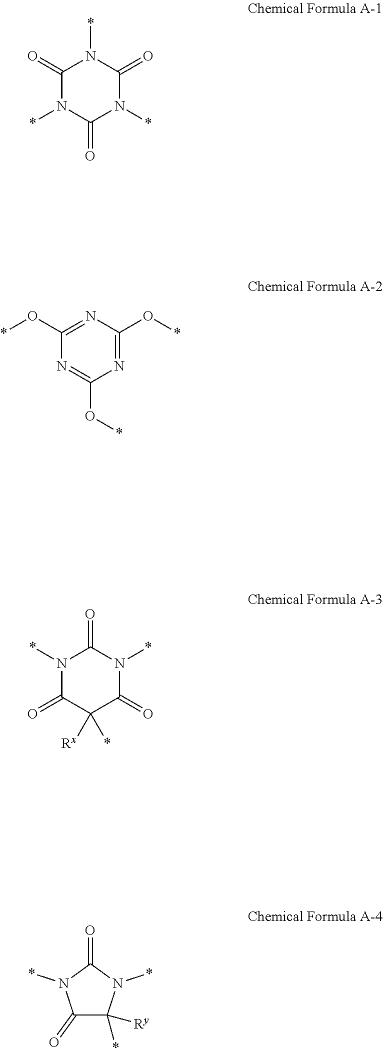

In Chemical Formula A-3 and Chemical Formula A-4,
R^{x} and R^{y} may each independently be hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C2 to C20 heteroaryl group, or a (e.g., any suitable) combination thereof, and
* is a linking point.

In Chemical Formula 3, L⁷ and L⁸ may each independently be a single bond (e.g., a single covalent bond), or a substituted or unsubstituted C1 to C10 alkylene group, and X⁶ and X⁷ may each independently be a single bond (e.g., a single covalent bond), or —(C═O)O—.

In Chemical Formula 4, L⁹ and L¹⁰ may each independently be a single bond (e.g., a single covalent bond), or a substituted or unsubstituted C1 to C10 alkylene group, X⁹ and X¹⁰ may each independently be a single bond (e.g., a single covalent bond), —C(═O)—, —(C═O)O—, —O(C═O)O—, or a (e.g., any suitable) combination thereof, and Y⁵ and Y⁶ may each independently be a substituted or unsubstituted C1 to C20 alkyl group.

In Chemical Formula 4, R⁴ to R⁶ may each independently be hydrogen, deuterium, a cyano group (—CN), a nitro group (—NO₂), —C(═O)OR^{d} (wherein, R^{d} is hydrogen, deuterium, or a substituted or unsubstituted C1 to C10 alkyl group), a substituted or unsubstituted C6 to C20 aryl group, or a (e.g., any suitable) combination thereof.

The polymer may include at least one structural unit selected from among (e.g., any one or more of the structural units represented by) Chemical Formula 2-1 and Chemical Formula 3-1.

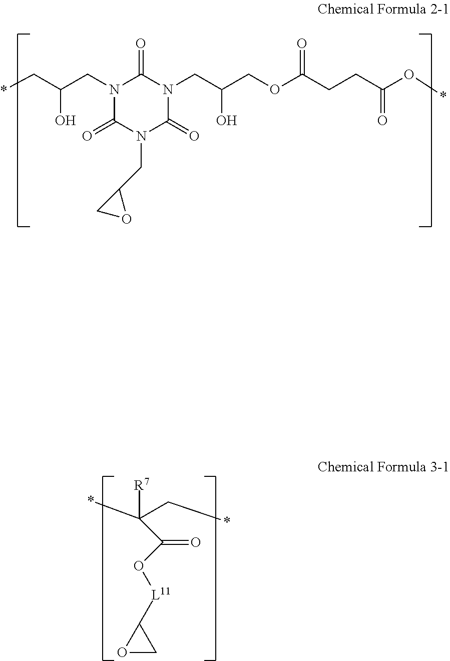

In Chemical Formula 3-1,
R⁷ may be hydrogen, deuterium, or a substituted or unsubstituted C1 to C5 alkyl group,
L¹¹ may be a substituted or unsubstituted C1 to C10 alkylene group, and
* is a linking point.

The protected imidazole compound may be represented by any one (e.g., one or more) of Chemical Formula 4-1 to Chemical Formula 4-6:

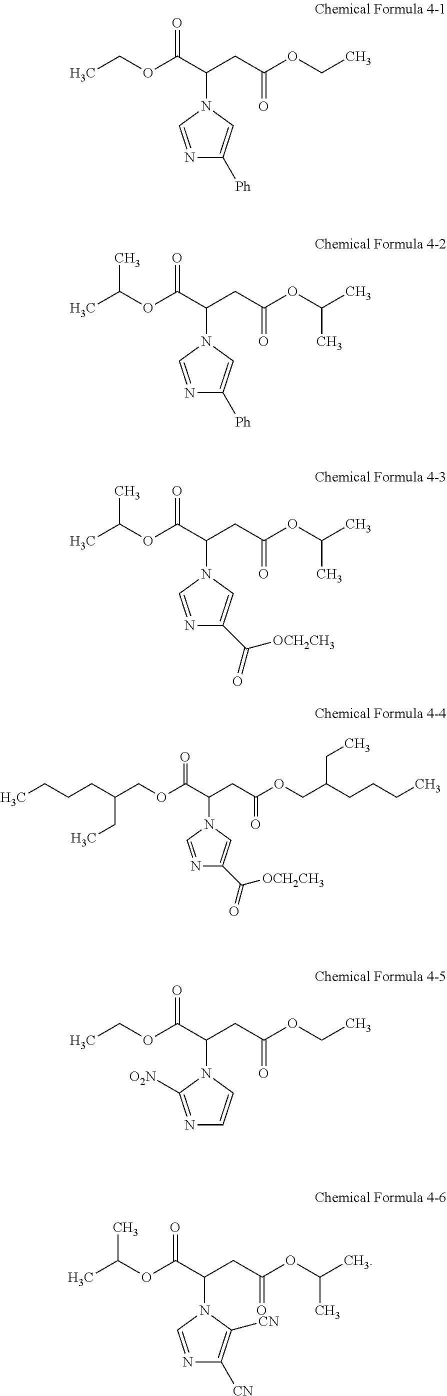

In Chemical Formula 4-1 and Chemical Formula 4-2, Ph may be a phenyl group.

A weight average molecular weight (Mw) of the polymer may be about 1,000 gram per mole (g/mol) to about 300,000 g/mol.

The polymer may be included in (e.g., may include) an amount of about 0.1 wt % to about 50 wt % based on a total weight of the resist underlayer composition.

A molecular weight of the compound may be about 300 g/mol to about 1,000 g/mol.

The compound may be included in (e.g., may include) an amount of about 0.01 wt % to about 30 wt % based on a total weight of the resist underlayer composition.

The composition may further include at least one (e.g., one or more) polymer(s) selected from among an acrylic resin, an epoxy resin, a novolac-based resin, a glycoluril-based resin, and a melamine-based resin.

The composition may further include an additive that may be any one of a surfactant, a thermal acid generator, a photoacid generator, a plasticizer, or a (e.g., any suitable) combination thereof.

According to one or more (e.g., some example) embodiments, a method of forming a pattern (e.g., photoresist pattern) includes forming an etching target layer on a substrate, forming a resist underlayer on the etching target layer by applying the resist underlayer composition according to one or more (e.g., some example) embodiments, forming a photoresist pattern on the resist underlayer, and sequentially etching the resist underlayer and the etching target layer using the photoresist pattern as an etching mask.

The resist underlayer composition according to one or more (e.g., some example) embodiments may enhance or improve patterning performance and energy efficiency. For example, the resist underlayer composition may enhance or improve sensitivity to an exposure light source, (e.g., even in a fine patterning process), and may concurrently or simultaneously (e.g., at the same time) provide a resist underlayer in which a pattern (e.g., photoresist pattern) is formed uniformly (or substantially uniformly).

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-6 are each a cross-sectional view illustrating a step (e.g., act or task) in a method of forming a pattern using a resist underlayer composition according to one or more embodiments of the present disclosure.

### DETAILED DESCRIPTION

Example embodiments of the present disclosure will hereinafter be described in more detail, so that they may be easily practiced by a person skilled in the art. However, the subject matter of this disclosure may be embodied in many different forms and is not construed as limited to the example embodiments set forth herein, rather the present disclosure is defined by the scope of claims. In this regard, the present embodiments may have different forms and should not be construed as being limited to the descriptions set forth herein. It should be appreciated that all changes, equivalents, and substitutes that do not depart from the spirit and technical scope are encompassed in the present disclosure.

In the drawings, the thickness of layers, films, panels, regions, and/or the like, may be exaggerated for clarity and like reference numerals designate like elements throughout the specification, and duplicative descriptions thereof may not be provided. It will be understood that if (e.g., when) an element such as a layer, film, region, or substrate is referred to as being “on” another element, it may be directly on the other element, or intervening elements may also be present. In contrast, if (e.g., when) an element is referred to as being “directly on” another element, there are no intervening elements present.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe certain elements, these elements should not be limited by these terms. These terms are only used to distinguish one element from another element. Thus, a first element could be termed a second element without departing from the teachings of the present disclosure. Similarly, a second element could be termed a first element.

As used herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, alternative language such as “or” is not to be construed as an exclusive meaning, for example, “A or B” is construed to include A, B, A+B, and/or the like. Similarly, the term “and/or” includes any and all combinations of one or more of the associated listed items. The symbol “/” used herein may be interpreted as “and” or as “or” according to the context.

As used herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added. The term “combination thereof” may include a mixture, a laminate, a complex, a copolymer, an alloy, a blend, a reactant of constituents.

As used herein, singular forms such as “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element. Similarly, alternative language such as “or” refers to “one or more” or “some” “embodiments of the present disclosure,” each including a corresponding listed item.

In this context, “consisting essentially of” means that any additional components will not materially affect the chemical, physical, optical or electrical properties of the semiconductor film.

As used herein, if (e.g., when) a definition is not otherwise provided, “substituted” refers to replacement of a hydrogen atom of a compound by a substituent selected from deuterium, a halogen (F, Br, Cl, or I), a hydroxyl group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a (e.g., any suitable) combination thereof.

In some embodiments, two adjacent substituents of the substituted halogen atom (F, Br, Cl, or I), hydroxyl group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused with each other to form a ring.

As used herein, “heterocyclic group” includes a heteroaryl group, and a cyclic group including at least one heteroatom selected from N, O, S, P, and Si instead of carbon (C) of a cyclic compound such as an aryl group, a cycloalkyl group, a fused ring thereof, or a (e.g., any suitable) combination thereof. If (e.g., when) the heterocyclic group is a fused ring, each or entire ring of the heterocyclic group may include at least one heteroatom.

For example, a substituted or unsubstituted aryl group and/or a substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiphenyl group, a substituted or unsubstituted carbazolyl group, a pyridoindolyl group, a benzopyridooxazinyl group, a benzopyridothiazinyl group, a 9,9-dimethyl-9,10-dihydroacridinyl group, a (e.g., any suitable) combination thereof, or a combined fused ring of the foregoing groups, but are not limited thereto.

As used herein, if (e.g., when) specific definition is not otherwise provided, the term “combination” refers to mixing or copolymerization.

Additionally, as used herein, “polymer” may include both oligomers and/or polymers.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In some embodiments, unless otherwise defined in the specification, “*” indicates a linking point of a structural unit or a moiety of a polymer.

### INTRODUCTION

In the semiconductor industry, there is a constant desire or demand to reduce the size of the semiconductor chips (e.g., including an integrated circuit). In order to meet this trend, a line width of the resist pattern (e.g., photoresist pattern) used in lithography technology may be desired to be, or should be, reduced to a level of (e.g., at most) several tens of nanometers, and the pattern (e.g., photoresist pattern) formed in this way is used to transfer a pattern (e.g., template circuit pattern) to a lower-positioned material by using an etching process on a lower-positioned substrate. However, as the pattern size of the resist (e.g., photoresist pattern) becomes smaller, a height (aspect ratio) of the resist (e.g., photoresist pattern) that can withstand or accommodate the line width is limited, and accordingly, the resist (e.g., photoresist pattern) may not have sufficient mass (e.g., physical resistance to undergo applied stress) in the etching step. Therefore, a resist underlayer has been used to compensate for this mass insufficiency, e.g., in a process if (e.g., when) a thin resist material is used, if (e.g., when) the substrate to be etched is thick, or if (e.g., when) a deep pattern is required or desired.

The resist underlayer may be desired or required to become thinner as the thickness of the resist becomes thinner, and the photoresist pattern should not collapse even if (e.g., when) the resist underlayer is thin. For this purpose, the resist underlayer should have excellent adhesion to the photoresist. In some embodiments, in forming a thin resist underlayer, coating uniformity of the resist underlayer composition and flatness of the resist underlayer produced therefrom should be enhanced or improved, and sensitivity to the exposure light source should be enhanced or improved, e.g., to enhance or improve pattern (e.g., photoresist pattern) formability and energy efficiency.

A resist underlayer composition according to some example embodiments includes a polymer including at least one of (e.g., selected from among) a structural unit represented by Chemical Formula 1, a structural unit represented by Chemical Formula 2, and a structural unit represented by Chemical Formula 3, a protected imidazole compound, and a solvent:

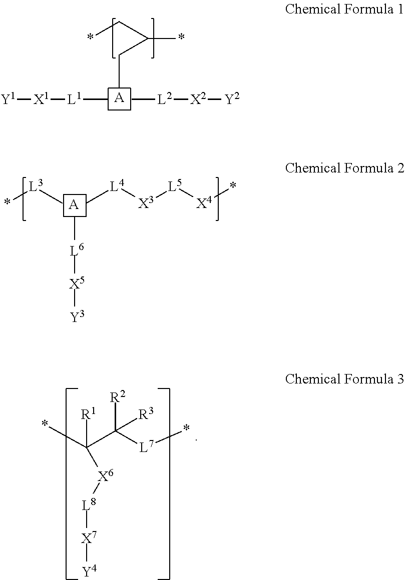

In Chemical Formula 1 to Chemical Formula 3,
A may be a heterocyclic group including a nitrogen atom in the ring (e.g., a ring-forming nitrogen atom),
L¹ to L⁸ may each independently be a single bond (e.g., a single covalent bond), a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a (e.g., any suitable) combination thereof,
X¹ to X⁷ may each independently be a single bond (e.g., a single covalent bond), —O—, —S—, —S(═O)—, —S(═O)₂—, —C(═O)—, —(C═O)O—, —O(C═O)O—, —NR^{a}— (wherein, R^{a} is hydrogen, deuterium, or a C1 to C10 alkyl group), or a (e.g., any suitable) combination thereof,
Y¹ and Y² may each independently be hydrogen, deuterium, a hydroxyl group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a (e.g., any suitable) combination thereof, provided at least one of (e.g., selected from among) Y¹ and Y² is an epoxy group,
Y³ and Y⁴ may each independently be an epoxy group,
R¹ to R³ may each independently be hydrogen, deuterium, or a substituted or unsubstituted C1 to C10 alkyl group, and
* is a linking point:

As used herein, “a protected imidazole compound” refers to a modified imidazole compound in which at least one hydrogen atom on a nitrogen and/or a carbon atom of the imidazole ring is replaced with a protecting group. The protecting group may be a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 heteroalkyl group, a substituted or unsubstituted C2 to C30 heteroalkenyl group, a substituted or unsubstituted C6 to C30 aryl group, a halogen atom, a hydroxyl group (—OH), a cyano group (—CN), a nitro group (—NO₂), a sulfonic acid group (—SO₃H), —C(═O)R^{c} (wherein, R^{c} is hydrogen, deuterium, or a substituted or unsubstituted C1 to C10 alkyl group), —C(═O)OR^{d} (wherein, R^{d} is hydrogen, deuterium, or a substituted or unsubstituted C1 to C10 alkyl group), or a (e.g., any suitable) combination thereof.

The protected imidazole compound may be represented by Chemical Formula 4:

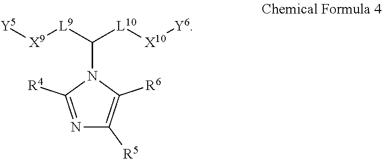

In Chemical Formula 4,
L⁹ and L¹⁰ may each independently be a single bond (e.g., a single covalent bond), a substituted or unsubstituted C1 to C20 alkylene group, or a substituted or unsubstituted C2 to C20 alkenylene group,
X⁹ and X¹⁰ may each independently be a single bond (e.g., a single covalent bond), —O—, —S—, —S(═O)—, —S(═O)₂—, —C(═O)—, —(C═O)O—, —O(C═O)O—, —NR^{b}— (wherein, R^{b} is hydrogen, deuterium, or a C1 to C10 alkyl group), or a (e.g., any suitable) combination thereof,
Y⁵ and Y⁶ may each independently be a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, or a (e.g., any suitable) combination thereof,
R⁴ to R⁶ may each independently be hydrogen, deuterium, a halogen atom, a hydroxyl group (—OH), a cyano group (—CN), a nitro group (—NO₂), a sulfonic acid group (—SO₃H), —C(═O)R^{c} (wherein, R^{c} is hydrogen, deuterium, or a substituted or unsubstituted C1 to C10 alkyl group), —C(═O)OR^{d} (wherein, R^{d} is hydrogen, deuterium, or a substituted or unsubstituted C1 to C10 alkyl group), a substituted or unsubstituted C1 to C10 alkyl group, a substituted or unsubstituted C6 to C20 aryl group, or a (e.g., any suitable) combination thereof.

The polymer including one or more of the structural units represented by Chemical Formula 1 to Chemical Formula 3 included in the composition according to some example embodiments includes an (e.g., at least one) epoxy group at a terminal end, and at least one imidazole protecting group. If (e.g., when) the composition is heat-treated, an imidazole moiety is generated as the protecting group of the compound is removed and the epoxy group may react to form a crosslinked structure between (e.g., individual molecules of) the polymer. Accordingly, the polymer may form a network structure, and the film properties of the resist underlayer may be enhanced or improved thereby. In embodiments, the resist underlayer prepared from the preceding composition may have a uniform (or substantially uniform) pattern.

The compound represented by Chemical Formula 4 included in the composition includes an imidazole moiety and may absorb or emit secondary electrons if (e.g., when) the resist underlayer composition is exposed to light. The secondary electrons may improve the sensitivity of the photoresist (e.g., by activating photoacid generators in the photoresist).

In some embodiments, the polymer including the structural unit represented by Chemical Formula 1 and the structural unit represented by Chemical Formula 2 includes a hetero ring including a nitrogen atom in the ring, so that the polymer including these structural units may have a sp²-sp² bond between polymers. This allows the polymer to have high electron density. If (e.g., when) it includes a polymer having high electron density, the underlayer composition according to some example embodiments may achieve or implement a film having a dense structure in the form of an ultra-thin film. In embodiments, the high electron density of the polymer may improve light absorption efficiency if (e.g., when) exposing the resist underlayer composition to light. In some embodiments, by including the heterocyclic skeleton, the etch selectivity may be enhanced or improved, and energy efficiency may be enhanced or improved if (e.g., when) forming patterns (e.g., photoresist patterns) after exposure using high-energy rays such as EUV (Extreme ultraviolet; wavelength of 13.5 nanometer (nm)) and/or electron beam (E-Beam).

A in Chemical Formula 1 and Chemical Formula 2 may be represented by any one of Chemical Formula A-1 to Chemical Formula A-4:

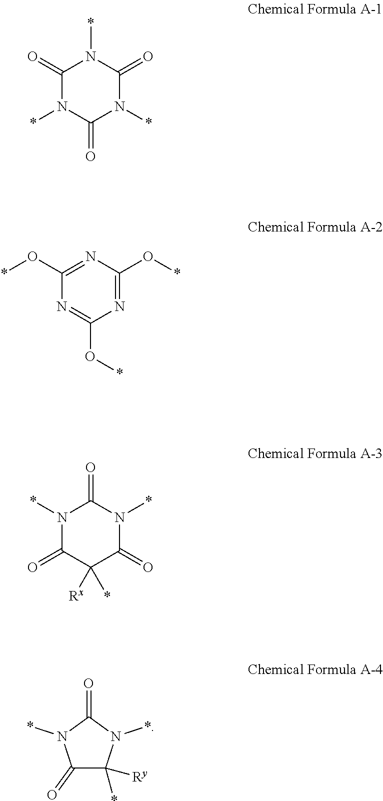

In Chemical Formula A-3 and Chemical Formula A-4,
R^{x} and R^{y} may each independently be hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C2 to C20 heteroaryl group, or a (e.g., any suitable) combination thereof, and
* is a linking point.

In some example embodiments, R^{x} and R^{y} may each independently be hydrogen, a substituted or unsubstituted C1 to C10 alkyl group, a substituted or unsubstituted C2 to C10 alkenyl group, or a substituted or unsubstituted C6 to C20 aryl group, for example hydrogen, or a substituted or unsubstituted C1 to C5 alkyl group, but are not limited thereto.

In some example embodiments, in Chemical Formula 1, L¹ and L² may each independently be a single bond (e.g., a single covalent bond), a substituted or unsubstituted C1 to C10 alkylene group, a substituted or unsubstituted C2 to C10 alkenylene group, or a (e.g., any suitable) combination thereof, for example, a single bond (e.g., a single covalent bond), a substituted or unsubstituted C1 to C5 alkylene group, or a (e.g., any suitable) combination thereof, but are not limited thereto.

In Chemical Formula 1, X¹ and X² may each independently be a single bond (e.g., a single covalent bond), —O—, —S—, —C(═O)—, —(C═O)O—, —O(C═O)O—, or a (e.g., any suitable) combination thereof, for example a single bond (e.g., a single covalent bond), —O—, —S—, —(C═O)O—, or a (e.g., any suitable) combination thereof, but are not limited thereto.

In Chemical Formula 1, Y¹ and Y² may each independently be hydroxyl group, a substituted or unsubstituted C1 to C10 alkyl group, a substituted or unsubstituted C2 to C10 alkenyl group, a substituted or unsubstituted C3 to C10 cycloalkyl group, a substituted or unsubstituted C6 to C10 aryl group, epoxy group, for example hydroxyl group, a substituted or unsubstituted C1 to C5 alkyl group, a substituted or unsubstituted C2 to C5 alkenyl group, a substituted or unsubstituted C6 to C10 aryl group, or epoxy group, but is not limited thereto. In the preceding, at least one of (e.g., selected from among) Y¹ and Y² may be an epoxy group.

In some example embodiments, in Chemical Formula 2, L³ to L⁶ may each independently be a single bond (e.g., a single covalent bond), a substituted or unsubstituted C1 to C10 alkylene group, or a substituted or unsubstituted C2 to C10 alkenylene group, for example a single bond (e.g., a single covalent bond), or a substituted or unsubstituted C1 to C10 alkylene group, for example a substituted or unsubstituted C1 to C5 alkylene group, but are not limited thereto. For example, L³ and L⁴ may each independently be a C1 to C5 alkylene group substituted with a hydroxyl group, but are not limited thereto.

In Chemical Formula 2, X³ to X⁵ may each independently be single bond (e.g., a single covalent bond), —O—, —C(═O)—, —(C═O)O—, or —O(C═O)O—, for example a single bond (e.g., a single covalent bond), —O—, or —(C═O)O—, for example —(C═O)O—, but are not limited thereto.

In some example embodiments, in Chemical Formula 3, each L⁷ may independently be a single bond (e.g., a single covalent bond), or a substituted or unsubstituted C1 to C10 alkylene group, for example a single bond (e.g., a single covalent bond), but is not limited thereto. Each L⁸ may independently be a single bond (e.g., a single covalent bond), a substituted or unsubstituted C1 to C10 alkylene group, or a substituted or unsubstituted C2 to C10 alkenylene group, for example a single bond (e.g., a single covalent bond), or a substituted or unsubstituted C1 to C10 alkylene group, for example a single bond (e.g., a single covalent bond), or unsubstituted C1 to C10 alkylene group, but is not limited thereto.

In Chemical Formula 3, X⁶ and X⁷ may each independently be a single bond (e.g., a single covalent bond), —O—, —C(═O)—, —(C═O)O—, or —O(C═O)O—, for example a single bond (e.g., a single covalent bond), —O—, —C(═O)—, or —(C═O)O—, for example a single bond (e.g., a single covalent bond), or —(C═O)O—, but are not limited thereto.

In Chemical Formula 3, R¹ to R³ may be hydrogen, deuterium, or a substituted or unsubstituted C1 to C5 alkyl group, for example hydrogen, a methyl group, or an ethyl group, but are not limited thereto.

In some example embodiments, in Chemical Formula 4, L⁹ and L¹⁰ may each independently be a single bond (e.g., a single covalent bond), or a substituted or unsubstituted C1 to C10 alkylene group, for example a single bond (e.g., a single covalent bond), or a substituted or unsubstituted C1 to C5 alkylene group, for example a single bond (e.g., a single covalent bond), a methylene group, or an ethylene group, but are not limited thereto.

In Chemical Formula 4, X⁹ and X¹⁰ may each independently be a single bond (e.g., a single covalent bond), —O—, —S—, —C(═O)—, —(C═O)O—, —O(C═O)O—, or a (e.g., any suitable) combination thereof, for example a single bond (e.g., a single covalent bond), —C(═O)—, —(C═O)O—, —O(C═O)O—, or a (e.g., any suitable) combination thereof, for example —(C═O)O—, but are not limited thereto.

In Chemical Formula 4, Y⁵ and Y⁶ may each independently be a substituted or unsubstituted C1 to C20 alkyl group, or a substituted or unsubstituted C2 to C20 alkenyl group, for example a substituted or unsubstituted C1 to C20 alkyl group, for example a substituted or unsubstituted C1 to C10 alkyl group, but are not limited thereto.

In Chemical Formula 4, R⁴ to R⁶ may each independently be hydrogen, deuterium, a cyano group (—CN), a nitro group (—NO₂), a sulfonic acid group (—SO₃H), —C(═O)R^{c} (wherein, R^{c} is hydrogen, deuterium, or a substituted or unsubstituted C1 to C10 alkyl group), —C(═O)OR^{d} (wherein, R^{d} is hydrogen, deuterium, or a substituted or unsubstituted C1 to C10 alkyl group), a substituted or unsubstituted C1 to C10 alkyl group, a substituted or unsubstituted C6 to C20 aryl group, or a (e.g., any suitable) combination thereof, for example, hydrogen, deuterium, a cyano group (—CN), a nitro group (—NO₂), —C(═O)OR^{d} (wherein, R^{d} is hydrogen, deuterium, or a substituted or unsubstituted C1 to C10 alkyl group), a substituted or unsubstituted C6 to C20 aryl group, or a (e.g., any suitable) combination thereof, hydrogen, a cyano group (—CN), a nitro group (—NO₂), —C(═O)OR^{d} (wherein, R^{d} is hydrogen, deuterium, a methyl group, an ethyl group, a propyl group, or a butyl group), a substituted or unsubstituted C6 to C10 aryl group, or a (e.g., any suitable) combination thereof, for example hydrogen, a cyano group (—CN), a nitro group (—NO₂), —C(═O)OCH₂CH₃, a substituted or unsubstituted phenyl group, or a (e.g., any suitable) combination thereof, but are not limited thereto.

In some example embodiments, the polymer may include at least one structural unit selected from among (e.g., any one or more of the structural units represented by) Chemical Formula 2-1 and Chemical Formula 3-1:

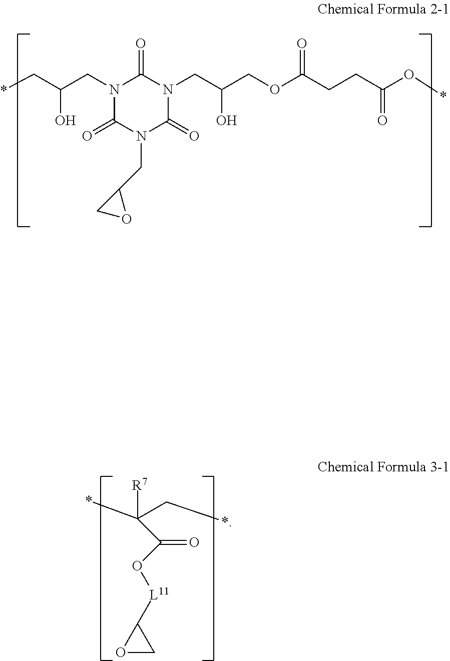

In Chemical Formula 3-1, R⁷ may be hydrogen, deuterium, or a substituted or unsubstituted C1 to C5 alkyl group, L¹¹ may be a substituted or unsubstituted C1 to C10 alkylene group, and * is a linking point.

In some example embodiments, the protected imidazole compound may be represented by at least any one (e.g., one or more) of Chemical Formula 4-1 to Chemical Formula 4-6:

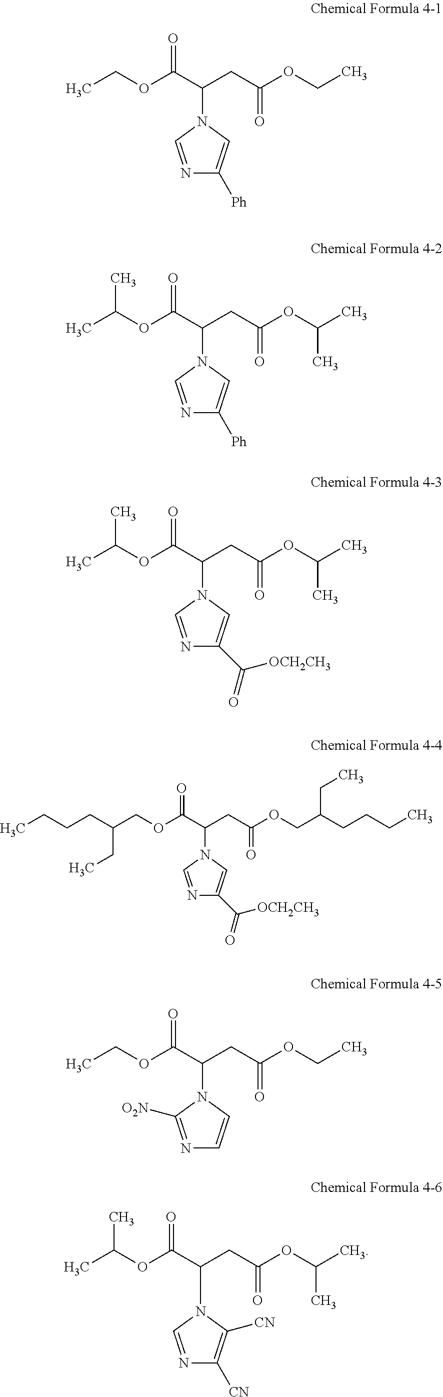

In Chemical Formula 4-1 and Chemical Formula 4-2, Ph may be a phenyl group.

The polymer may have a weight average molecular weight of about 1,000 gram per mole (g/mol) to about 300,000 g/mol, for example about 3,000 g/mol to about 200,000 g/mol, for example about 3,000 g/mol to about 100,000 g/mol, for example about 3,000 g/mol to about 90,000 g/mol, for example about 3,000 g/mol to about 70,000 g/mol, for example about 3,000 g/mol to about 60,000 g/mol, for example about 3,000 g/mol to about 50,000 g/mol, for example about 5,000 g/mol to about 50,000 g/mol, for example about 5,000 g/mol to about 30,000 g/mol, but is not limited thereto. By having a weight average molecular weight within the preceding ranges, a carbon content and solubility in the solvent of the resist underlayer composition including the polymer may be adjusted and optimized or enhanced.

The polymer may be included in an amount of about 0.1 wt % to about 50 wt % based on a total weight of the resist underlayer composition. For example, the polymer may be included in an amount of about 10 wt % to about 50 wt %, for example about 20 wt % to about 50 wt %, for example about 20 wt % to about 30 wt % based on a total weight of the resist underlayer composition, but is not limited thereto. By including the polymer within the preceding ranges in the composition, the thickness, surface roughness, and a degree of planarization of the resist underlayer may be adjusted and enhanced.

The protected imidazole compound may have a molecular weight of about 300 g/mol to 1,000 g/mol, for example about 300 g/mol to about 900 g/mol, for example about 300 g/mol to about 800 g/mol, for example about 300 g/mol to about 700 g/mol, for example about 300 g/mol to about 600 g/mol, for example about 300 g/mol to about 500 g/mol, but is not limited thereto. Because the protected imidazole compound has a molecular weight in the preceding range, the carbon content and solubility in the solvent of the resist underlayer composition including the compound can be adjusted and optimized or enhanced.

The protected imidazole compound may be included in an amount of about 0.01 wt % to about 30 wt % based on a total weight of the resist underlayer composition. For example, the compound may be included in an amount of about 0.1 wt % to about 30.0 wt %, for example about 1.0 wt % to about 30.0 wt %, for example about 5.0 wt % to about 30.0 wt %, for example about 5.0 wt % to about 25.0 wt %, for example about 8.0 wt % to about 25.0 wt %, for example about 10.0 wt % to about 25.0 wt % based on a total weight of the resist underlayer composition, but is not limited thereto. By including the protected imidazole compound in the preceding ranges, the thickness, surface roughness, chemical resistance, and degree of planarization of the resist underlayer can be adjusted and enhanced.

The resist underlayer composition according to some example embodiments may include a solvent. The solvent is not particularly limited as long as it has suitable or sufficient solubility and/or dispersibility for the polymer and/or compound according to some example embodiments, but may be, for example, propylene glycol, propylene glycol diacetate, methoxy propanediol, diethylene glycol, diethylene glycol butyl ether, tri(ethylene glycol)monomethylether, propylene glycol monomethylether, propylene glycol monomethylether acetate (PGMEA), cyclohexanone, ethyl acetate, gamma-butyrolactone, N,N-dimethyl formamide, N,N-dimethyl acetamide, methylpyrrolidone, methyl pyrrolidinone, methyl 2-hydroxyisobutyrate, acetylacetone, ethyl 3-ethoxypropionate, or a (e.g., any suitable) combination thereof.

The resist underlayer composition according to some example embodiments may further include at least one (e.g., one or more) polymer(s) selected from among an acrylic resin, an epoxy resin, a novolac-based resin, a glycoluril-based resin, and a melamine-based resin, in addition to the polymer, compound, and solvent, but is not limited thereto.

The resist underlayer composition according to some example embodiments may further include an additive including at least one of a surfactant, a thermal acid generator, a photoacid generator, a plasticizer, or a (e.g., any suitable) combination thereof.

The surfactant may (e.g., be used to) enhance or improve coating defects caused by an increase in a solid content if (e.g., when) forming the resist underlayer, and may be, for example, an alkyl benzenesulfonate salt, an alkyl pyridinium salt, polyethylene glycol, a quaternary ammonium salt, and/or the like, but is not limited thereto.

The thermal acid generator may be an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carbonic acid, benzointosylate, 2-nitrobenzyltosylate, and/or the like, or a (e.g., any suitable) combination thereof, but is not limited thereto. For example, one or more other organic sulfonic acid alkyl ester(s) may be used as the thermal acid generator.

The plasticizer is not particularly limited, and a variety of suitable plasticizers generally used in the art may be used. Examples of a plasticizer may include low molecular compounds such as phthalic acid esters, adipic acid esters, phosphoric acid esters, trimellitic acid esters, citric acid esters, and/or the like, polyether compounds, polyester-based compounds, polyacetal compounds, and/or the like.

The additive may be included in an amount of about 0.0001 to about 40 parts by weight based on 100 parts by weight of the resist underlayer composition. Within the described range, solubility may be improved while optical properties of the resist underlayer composition are not (or substantially not) changed.

According to some example embodiments, a resist underlayer manufactured using the aforementioned resist underlayer composition is provided. The resist underlayer may be formed by coating the aforementioned resist underlayer composition on, for example, a substrate and then curing through a heat treatment process.

### Method of Forming a Photoresist Pattern

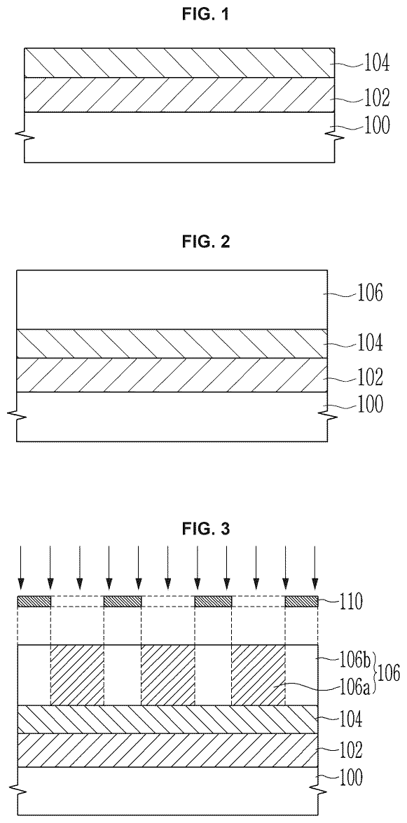

Hereinafter, a method of forming a pattern (e.g., photoresist pattern) using the aforementioned resist underlayer composition is described with reference to FIGS. 1 to 6.

FIGS. 1 to 6 are each a cross-sectional view illustrating a step (e.g., act or task) of a method of forming a pattern (e.g., photoresist pattern) using the resist underlayer composition according to the present disclosure.

Referring to FIG. 1, an etching target is prepared. The etching target may be a thin film 102 formed on a semiconductor substrate 100. Hereinafter, the etching target is limited to the thin film 102. An entire surface of the thin film 102 may be pre-washed to remove impurities and/or the like (e.g., remaining) thereon. The thin film 102 may be or include, for example, a silicon nitride layer, a polysilicon layer, or a silicon oxide layer.

Subsequently, the aforementioned resist underlayer composition is coated on the surface of the cleaned thin film 102 by utilizing a spin coating method.

Then, the coated composition is dried and baked to form a resist underlayer 104 on the thin film 102. For example, a first baking process may be performed at a temperature of about 100° C. to about 500° C., for example about 100° C. to about 300° C. For example, the resist underlayer composition is described in more detail elsewhere herein and thus will not be repeated.

Referring to FIG. 2, a photoresist film 106 is formed by coating a photoresist on the resist underlayer 104.

Examples of the photoresist may be a positive-type (or kind) photoresist including a naphthoquinonediazide compound and a novolac resin, a chemically-amplified positive photoresist including an acid generator capable of dissociating acid through exposure, a compound decomposed under presence of the acid and having increased dissolubility in an alkali aqueous solution, and an alkali soluble resin, a chemically-amplified positive-type (or kind) photoresist including an alkali-soluble resin capable of applying a resin increasing dissolubility in an alkali aqueous solution, and/or the like.

Then, the semiconductor substrate 100 having the photoresist film 106 is primarily baked. The primary baking may be performed at a temperature of about 90° C. to about 120° C.

Referring to FIG. 3, the photoresist film 106 may be selectively exposed. Exposure of the photoresist film 106 may be for example performed by positioning an exposure mask 110 having a set or predetermined pattern on a mask stage (e.g., of an exposure apparatus) and aligning the exposure mask 110 on the photoresist film 106. Subsequently, light may be irradiated into (e.g., through) the exposure mask such that a set or predetermined region of the photoresist film 106 formed on the substrate 100 may react (e.g., selectively reacts) with light passing (e.g., through) the exposure mask 110 (e.g., by light originally irradiated into (e.g., through) the exposure mask 110).

For example, the light used during the exposure may include electromagnetic radiation selected from among short wavelength light such as an i-line having a wavelength of 365 nanometer (nm), a KrF excimer laser having a wavelength of 248 nm, and/or an ArF excimer laser having a wavelength of 193 nm. In some embodiments, EUV (extreme ultraviolet) radiation having a wavelength of 13.5 nm (e.g., corresponding to extreme ultraviolet light) may be used.

The photoresist film of the exposed region 106a has a relatively different hydrophilicity compared with the photoresist film of the unexposed region 106b. Accordingly, the exposed region 106a and non-exposed region 106b of the photoresist film each may have a different solubility from each other.

Subsequently, the substrate 100 is secondarily baked. The secondary baking may be performed at a temperature of about 90° C. to about 150° C. The exposed region 106a of the photoresist film becomes easily dissoluble in a set or predetermined solvent due to the secondary baking.

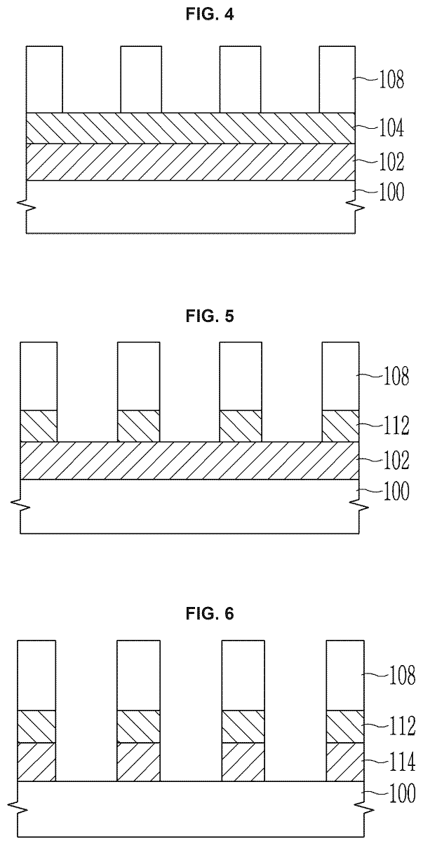

Referring to FIG. 4, for example, the portion of the photoresist film 106 corresponding to the exposed region 106a is dissolved and then removed using tetramethyl ammonium hydroxide (TMAH), and/or the like, and thereby the portion of the photoresist film 106 corresponding to the unexposed region 106b (e.g., remaining after development) forms the photoresist pattern 108.

Subsequently, the resist underlayer 104 may be etched using the photoresist pattern 108 as an etch mask. An organic film pattern 112 as shown in FIG. 5 may be formed through the preceding etching process. The etching (e.g., of the resist underlayer 104) may be, for example, performed by a dry etching process using an etching gas, and the etching gas may be, for example, CHF₃, CF₄, Cl₂, O₂, and/or a (e.g., any suitable) mixed gas thereof. As described herein, because the resist underlayer 104 formed by the resist underlayer composition according to one or more embodiments has a relatively fast etch rate, a smooth etching process may be performed within a relatively short time.

In one or more embodiments, the resist underlayer 104 may have a thickness of about 10 angstrom (Å) to about 300 Å, or about 30 Å to about 150 Å, or about 40 Å to about 60 Å.

Referring to FIG. 6, the photoresist pattern 108 may be applied as an etching mask to etch an exposed thin film 102. As a result, the thin film 102 may be formed into a thin film pattern 114. In the exposure process described as performed previously, the thin film pattern 114 formed by an exposure process performed using a short wavelength light source (e.g., such as an i-line (a wavelength of 365 nm), a KrF excimer laser (a wavelength of 248 nm), and/or an ArF excimer laser (a wavelength of 193 nm)) may have a width of tens of nanometers (e.g., at least two dozen) to hundreds (e.g., at least two hundred) nanometers, and the thin film pattern 114 formed by an exposure process performed using an EUV light source may have a width of less than, or equal to, about 20 nm.

In one or more embodiments, the method may include use of a light source (e.g., electromagnetic radiation in an exposure process) having a wavelength of about 5 nanometer (nm) to about 500 nm, or about 10 nm to about 20 nm.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

Hereinafter, the subject matter of the present disclosure is described in more detail through Examples regarding synthesis of the polymer and preparation of a resist underlayer composition including the same. However, the present disclosure is technically not restricted by the following examples.

### EXAMPLES

### Synthesis Example 1

33.17 g of propylene glycol monomethylether acetate (PGMEA) is added to a 500 mL 2-necked round flask under a nitrogen atmosphere and after connecting a condenser to the flask, heated to 90° C. Subsequently, a solution prepared by dissolving 71.08 g of glycidyl methacrylate (Samchun Chemical Co., Ltd.) and 17.27 g of dimethyl 2,2′-azobis (2-methylpropionate) (V-601, Wako Chemicals Corp.) in 132.67 g of PGMEA is added dropwise thereto for 1 hour and then, reacted for 3 hours and then, cooled to room temperature. Then, the resultant reaction solution is transferred to a 1 L wide-mouth bottle, and 450 g of heptane is added thereto, while stirring to generate a gum, which is then dissolved in 150 g of tetrahydrofuran (THF). The corresponding solution is treated with heptane to remove monomolecules (monomers) and low molecular weight molecules and then, dried to obtain a polymer composed of a structural unit represented by Chemical Formula 3-2. (Mw=3,900 g/mol)

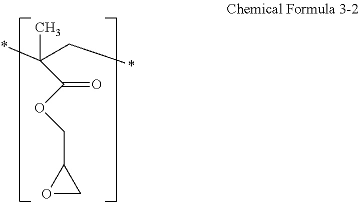

### Synthesis Example 2

42.61 g of PGMEA is added to a 500 mL 2-necked round flask under a nitrogen atmosphere and after connecting a condenser to the flask, heated to 80° C. Subsequently, a solution prepared in dissolving 51.25 g of glycidyl acrylate (TCI (Tokyo Chemical Industry)) and 27.63 g of dimethyl 2,2′-azobis (2-methylpropionate) (V-601) in 170.43 g of PGMEA is added dropwise thereto for 1 hour and then, reacted for 3 hours and cooled to room temperature. Then, the resultant reaction solution is transferred to a 1 L wide-mouth bottle, and 450 g of heptane is added thereto, while stirring to generate a gum, which is then dissolved in 150 g of tetrahydrofuran (THF). The corresponding solution is treated with heptane to remove monomolecules (monomers) and low molecular weight molecules and then, dried to finally obtain a copolymer composed of structural units represented by Chemical Formulas 3-3 and 5. (Mw=8,800 g/mol)

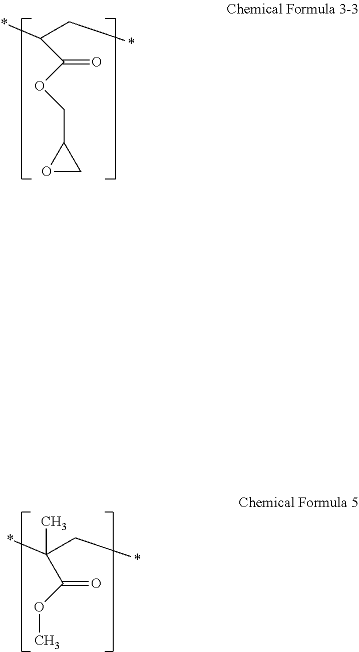

### Synthesis Example 3

38.12 g of PGMEA is added to a 500 mL 2-necked round flask under a nitrogen atmosphere and after connecting a condenser to the flask, heated to 80° C. Subsequently, a solution prepared by dissolving 28.43 g of glycidyl methacrylate (Samchun Chemical Co., Ltd.), 53.26 g of 4-benzoylphenyl methacrylate (TCI (Tokyo Chemical Industry)), and 13.82 g (60 mmol) of dimethyl 2,2′-azobis (2-methylpropionate) (V-601, Wako Chemicals Corp.) in 152.49 g of PGMEA is added dropwise thereto for 1 hour and then, reacted for 3 hours and cooled to room temperature. Then, the resultant reaction solution is transferred to a 1 L wide-mouth bottle, and 450 g of heptane is added thereto, while stirring to generate a gum, which is then dissolved in 150 g of tetrahydrofuran (THF). The corresponding solution is treated by using heptane to remove monomolecules (monomers) and low molecular weight molecules and then, dried to finally obtain a copolymer composed of structural unit represented by Chemical Formulas 3-2 and 6. (Mw=7,000 g/mol)

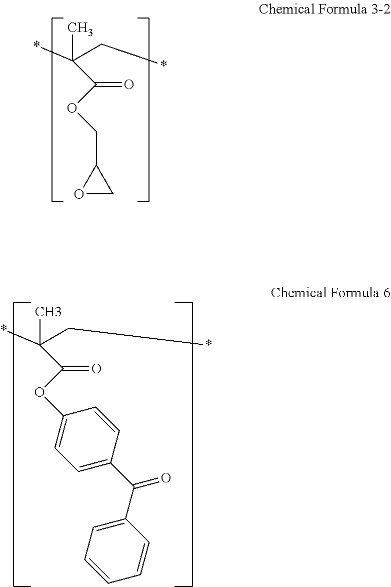

### Synthesis Example 4

148.6 g of 1,3,5-triglycidyl isocyanurate, 60.0 g of butanedioic acid, 9.1 g of benzyl triethyl ammonium chloride, and 350 g of N,N-dimethylformamide are added to a 1 L 2-necked round flask, and a condenser is connected to the flask. Subsequently, the resultant reaction solution is reacted for 8 hours by increasing a temperature to 100° C. and then, cooled to room temperature (23° C.). Subsequently, the reaction solution is transferred to a 1 L wide-mouth bottle and then, 3 times washed with hexane and subsequently with purified water. The obtained gum-like resin is completely dissolved in 80 g of THE and then, slowly added to 700 g of toluene, while stirring, and the solvent is removed therefrom. Finally, a polymer composed of a structural unit represented by Chemical Formula 1-3 is obtained. (Mw=7,500 g/mol)

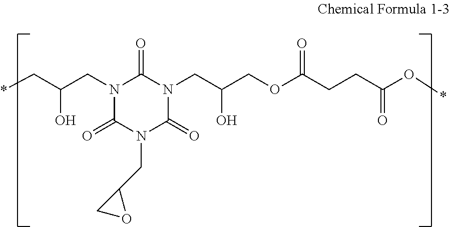

### Synthesis Example 5

43.25 g of 4-phenylimidazole, 40.04 g of diisopropyl fumarate, and 192.40 g of PGMEA are added to a 500 mL 2-necked round flask, and 3.05 g of 1,8-diazabicyclo(5.4.0)undec-7-ene (DBU) is added dropwise thereto and then, reacted at room temperature for 24 hours. The corresponding reaction solution is washed with distilled water, treated with MgSO₄ to remove moisture, and purified through column chromatography using silica gel to obtain a compound represented by Chemical Formula 4-2. (molecular weight: 345.41 g/mol)

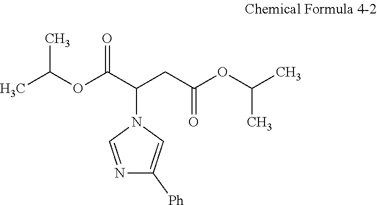 [SMILES: CC(C)OC(=O)CC(C(=O)OC(C)C)n1cnc(-c2ccccc2)c1]

### Synthesis Example 6

42.04 g of ethyl 4-imidazolecarboxylate, 68.11 g of bis(2-ethylhexyl) fumarate, and 192.4 g of PGMEA are added to a 500 mL 2-necked round flask, 3.05 g (20 mmol) of 1,8-diazabicyclo(5.4.0)undec-7-ene (DBU) is added dropwise thereto and then, reacted at room temperature for 24 hours. The resultant reaction solution is washed with distilled water, treated with MgSO₄ to remove moisture, and purified through column chromatography using silica gel to finally obtain a compound represented by Chemical Formula 4-4. (molecular weight: 480.65 g/mol)

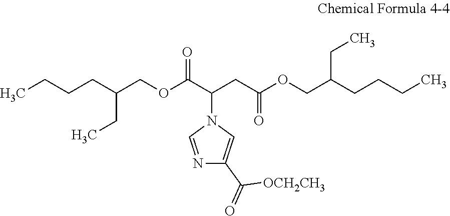 [SMILES: CCCCC(CC)COC(=O)CC(C(=O)OCC(CC)CCCC)n1cnc(C(=O)OCC)c1]

### Preparation of Resist Underlayer Compositions

### Examples 1 to 8 and Comparative Examples 1 to 4

Each resist underlayer composition was prepared by dissolving a polymer, a compound, and a thermal acid generator in PGMEA, each in the amounts shown in Table 1. In Table 1, PPTS is pyridinium p-toluenesulfonate, and PD1174 is a glycoluril-based crosslinker from TCI (Tokyo Chemical Industry).

TABLE 1

| | | | Thermal |
|---|---|---|---|
| | | | acid |
| | Polymer | Compound | generator |
| | (wt %) | (wt %) | (wt %) |
| Example 1 | Synthesis Example | Synthesis Example | — |
| | 1 (2.4) | 5 (0.6) | |
| Example 2 | Synthesis Example | Synthesis Example | — |
| | 2 (2.4) | 5 (0.6) | |
| Example 3 | Synthesis Example | Synthesis Example | — |
| | 3 (2.4) | 5 (0.6) | |
| Example 4 | Synthesis Example | Synthesis Example | — |
| | 4 (2.4) | 5 (0.6) | |
| Example 5 | Synthesis Example | Synthesis Example | — |
| | 1 (2.4) | 6 (0.6) | |
| Example 6 | Synthesis Example | Synthesis Example | — |
| | 2 (2.4) | 6 (0.6) | |
| Example 7 | Synthesis Example | Synthesis Example | — |
| | 3 (2.4) | 6 (0.6) | |
| Example 8 | Synthesis Example | Synthesis Example | — |
| | 4 (2.4) | 6 (0.6) | |
| Comparative | Synthesis Example | PD1174 (0.6) | PPTS (0.06) |
| Example 1 | 1 (2.4) | | |
| Comparative | Synthesis Example | PD1174 (0.6) | PPTS (0.06) |
| Example 2 | 2 (2.4) | | |
| Comparative | Synthesis Example | PD1174 (0.6) | PPTS (0.06) |
| Example 3 | 3 (2.4) | | |
| Comparative | Synthesis Example | PD1174 (0.6) | PPTS (0.06) |
| Example 4 | 4 (2.4) | | |

### Evaluation 1: Evaluation of Exposure Characteristics

Each of the compositions according to Examples 1 to 8 and Comparative Examples 1 to 4 was taken by 2 mL and then, spin-coated on an 8-inch wafer at a main spin speed of 1,500 rpm for 20 seconds by using auto track (ACT-8, TEL (Tokyo Electron Limited)) and cured at 205° C. for 60 seconds to form a 50 angstrom (Å)-thick resist underlayer. Subsequently, on the aforementioned underlayer, a photoresist solution was spin-on coated and then, heat-treated on a hot plate at 110° C. for 1 minutes to form a photoresist layer. The photoresist layer was exposed by using an electron beam (e-beam) light exposer (Elionix, Inc.) and then, heat-treated at 150° C. for 60 seconds. Subsequently, the photoresist layer was developed with a 2.38 mass % tetramethyl ammonium hydroxide (TMAH) aqueous solution and rinsed with pure water for 15 seconds to form a line and space (US) photoresist pattern. Then, the photoresist pattern was evaluated with respect to an optimal exposure dose.

### Evaluation 2: Evaluation of Line Width Roughness (LWR)

Each of the compositions according to Examples 1 to 8 and Comparative Examples 1 to 4 was spin-on coated and heat-treated on a hot plate at 205° C. for 60 seconds to form a 50 angstrom (Å)-thick resist underlayer. Subsequently, on the aforementioned underlayer, a photoresist solution was spin-on coated and heat-treated on a hot plate at 110° C. for 1 minute to form a photoresist layer. The photoresist layer was exposed by using an e-beam light exposer (an acceleration voltage: 100 kiloelectron volt (keV), Elionix Inc.). Subsequently, the exposed photoresist layer was heat-treated at 95° C. for 60 seconds, developed with a 2.38 wt % TMAH aqueous solution for 60 seconds, and rinsed with pure water for 15 seconds to form a photoresist pattern.

The formed photoresist pattern was examined with respect to line width roughness (LWR) with a scanning electron microscope (SEM) S-9260 (Hitachi, Ltd.) to measure a distance from a reference line where an edge should be within a range of 2 micrometer (μm) in a length direction of the photoresist pattern.

The exposure doses and LWR according to Examples 1 to 8 and Comparative Examples 1 to 4 were converted into a ratio based on the exposure dose or LWR of Comparative Example 1 as a reference, and the results are shown in Table 2, wherein a smaller exposure dose and a smaller line width roughness (LWR) are each associated with enhanced or improved (e.g., better) photoresist pattern formation and sensitivity.

Exposure dose (or LWR) (%)=(Exposure dose (or LWR) according to each Experimental Example−Exposure dose (or LWR) according to Comparative Example 1)/Exposure dose (or LWR) according to Comparative Example 1×100

TABLE 2

| | Exposure dose (%) | LWR (%) |
|---|---|---|
| Example 1 | −5.2 | −6.5 |
| Example 2 | −4.2 | −5.1 |
| Example 3 | −7.5 | −5.7 |
| Example 4 | −4.8 | −6.2 |
| Example 5 | −4.7 | −6.2 |
| Example 6 | −4.0 | −4.8 |
| Example 7 | −7.1 | −5.1 |
| Example 8 | −4.1 | −5.9 |
| Comparative Example 1 | — | — |
| Comparative Example 2 | 1.2 | 2.5 |
| Comparative Example 3 | −1.4 | 3.4 |
| Comparative Example 4 | 0.6 | 1.1 |

Referring to Table 2, the resist underlayers of Examples 1 to 8, when compared with those of Comparative Examples 1 to 4, were confirmed to exhibit excellent or suitable fine photoresist pattern (US) formation and sensitivity. In some embodiments, the resist underlayers of Examples 1 to 8, compared with those of Comparative Examples 1 to 4, had smaller LWR, which confirmed that a more uniform photoresist pattern(s) was produced.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Hereinbefore, one or more embodiments of the present disclosure have been described and illustrated, however, it should be apparent to a person with ordinary skill in the art that the present disclosure is not limited to the embodiments as described. Rather, the one or more embodiments may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims, and equivalents thereof.

Reference Numerals

| | |
|---|---|
| 100: substrate | 102: thin film |
| 104: resist underlayer | 106: photoresist film |
| 106a: exposed region | 106b: unexposed region |
| 108: photoresist pattern | 110: mask |
| 112: organic film pattern | 114: thin film pattern |

What is claimed is:

1. A resist underlayer composition, comprising:
a polymer comprising:
at least one selected from among a structural unit represented by Chemical Formula 1, a structural unit represented by Chemical Formula 2, and a structural unit represented by Chemical Formula 3;
a protected imidazole compound; and
a solvent, 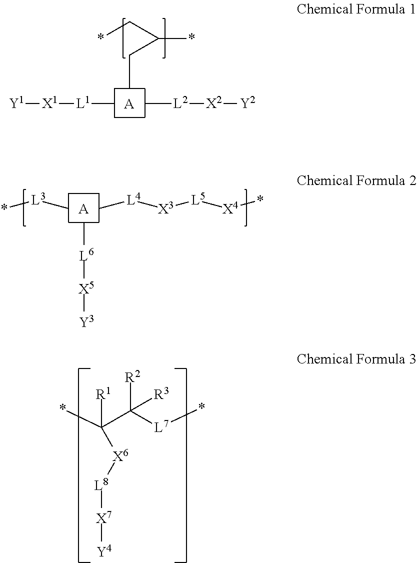
wherein, in Chemical Formula 1 to Chemical Formula 3,
A is a heterocyclic group comprising a ring-forming nitrogen atom,
L¹ to L⁸ are each independently a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,
X¹ to X⁷ are each independently a single bond, —O—, —S—, —S(═O)—, —S(═O)₂—, —C(═O)—, —(C═O)O—, —O(C═O)O—, —NR^{a}—, or a combination thereof,
R^{a} is hydrogen, deuterium, or a C1 to C10 alkyl group,
Y¹ and Y² are each independently hydrogen, deuterium, a hydroxyl group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a combination thereof, provided at least one of Y¹ and Y² is an epoxy group,
Y³ and Y⁴ are each independently an epoxy group,
R¹ to R³ are each independently hydrogen, deuterium, or a substituted or unsubstituted C1 to C10 alkyl group, and
* is a linking point.

2. The resist underlayer composition as claimed in claim 1, wherein the protected imidazole compound is represented by Chemical Formula 4: 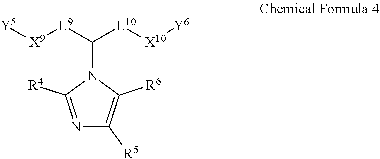
wherein, in Chemical Formula 4,
L⁹ and L¹⁰ are each independently a single bond, a substituted or unsubstituted C1 to C20 alkylene group, or a substituted or unsubstituted C2 to C20 alkenylene group,
X⁹ and X¹⁰ are each independently a single bond, —O—, —S—, —S(═O)—, —S(═O)₂—, —C(═O)—, —(C═O)O—, —O(C═O)O—, —NR^{b}—, or a combination thereof,
R^{b} is hydrogen, deuterium, or a C1 to C10 alkyl group,
Y⁵ and Y⁶ are each independently a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, or a combination thereof,
R⁴ to R⁶ are each independently hydrogen, deuterium, a halogen atom, a hydroxyl group (—OH), a cyano group (—CN), a nitro group (—NO₂), a sulfonic acid group (—SO₃H), —C(═O)R^{c}, —C(═O)OR^{d}, a substituted or unsubstituted C1 to C10 alkyl group, a substituted or unsubstituted C6 to C20 aryl group, or a combination thereof, and
R^{c} and R^{d} are each independently a hydrogen, deuterium, or a substituted or unsubstituted C1 to C10 alkyl group.

3. The resist underlayer composition as claimed in claim 1, wherein A in Chemical Formula 1 and Chemical Formula 2 is represented by any one of Chemical Formula A-1 to Chemical Formula A-4: 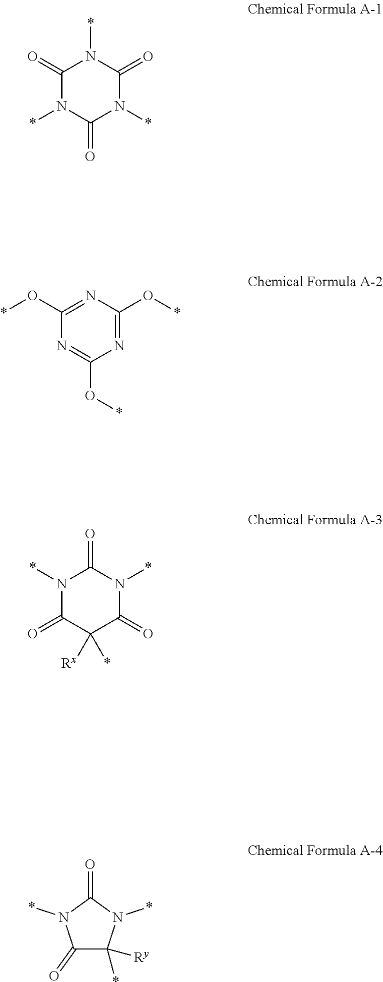
wherein, in Chemical Formula A-3 and Chemical Formula A-4,
R^{x} and R^{y} are each independently hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C2 to C20 heteroaryl group, or a combination thereof, and
* is a linking point.

4. The resist underlayer composition as claimed in claim 1, wherein in Chemical Formula 3, L⁷ and L⁸ are each independently a single bond, or a substituted or unsubstituted C1 to C10 alkylene group, and X⁶ and X⁷ are each independently a single bond, or —(C═O)O—.

5. The resist underlayer composition as claimed in claim 2, wherein in Chemical Formula 4, L⁹ and L¹⁰ are each independently a single bond, or a substituted or unsubstituted C1 to C10 alkylene group, X⁹ and X¹⁰ are each independently a single bond, —C(═O)—, —(C═O)O—, —O(C═O)O—, or a combination thereof, and Y⁵ and Y⁶ are each independently a substituted or unsubstituted C1 to C20 alkyl group.

6. The resist underlayer composition as claimed in claim 5, wherein in Chemical Formula 4, R⁴ to R⁶ are each independently hydrogen, deuterium, a cyano group (—CN), a nitro group (—NO₂), —C(═O)OR^{d}, a substituted or unsubstituted C6 to C20 aryl group, or a combination thereof, and
R^{d} is hydrogen, deuterium, or a substituted or unsubstituted C1 to C10 alkyl group.

7. The resist underlayer composition as claimed in claim 1, wherein the polymer comprises at least one structural unit selected from among Chemical Formula 2-1 and Chemical Formula 3-1: 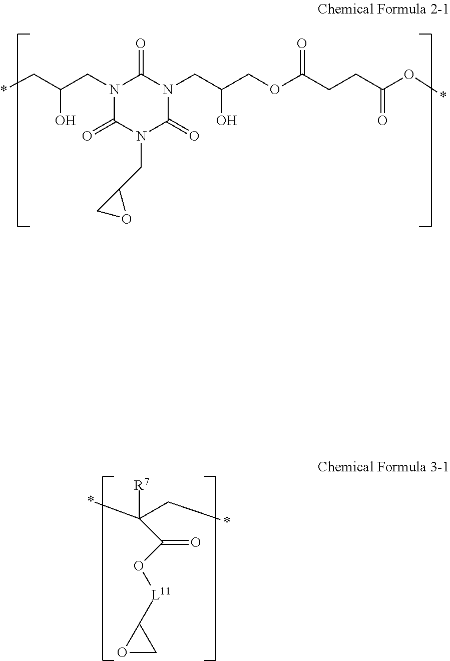
wherein, in Chemical Formula 3-1,
R⁷ is hydrogen, deuterium, or a substituted or unsubstituted C1 to C5 alkyl group,
L¹¹ is a substituted or unsubstituted C1 to C10 alkylene group, and
* is a linking point.

8. The resist underlayer composition as claimed in claim 1, wherein the protected imidazole compound is represented by any one of Chemical Formula 4-1 to Chemical Formula 4-6: 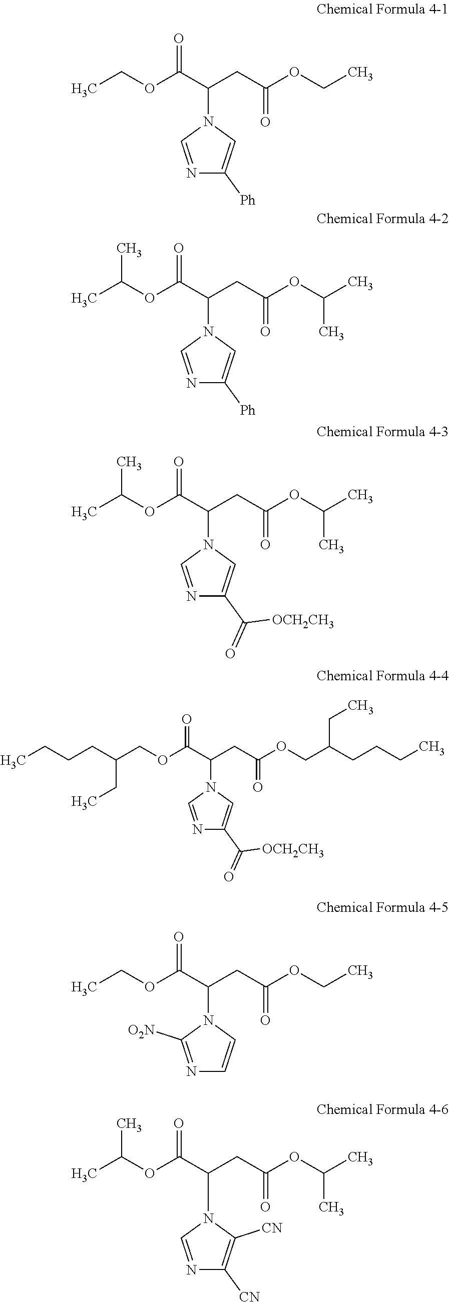
wherein, in Chemical Formula 4-1 and Chemical Formula 4-2, Ph is a phenyl group.

9. The resist underlayer composition as claimed in claim 1, wherein a weight average molecular weight of the polymer is about 1,000 gram per mole (g/mol) to about 300,000 g/mol.

10. The resist underlayer composition as claimed in claim 1, wherein the polymer comprises an amount of about 0.1 wt % to about 50 wt % based on a total weight of the resist underlayer composition.

11. The resist underlayer composition as claimed in claim 1, wherein a molecular weight of the protected imidazole compound is about 300 g/mol to about 1,000 g/mol.

12. The resist underlayer composition as claimed in claim 1, wherein the protected imidazole compound comprises an amount of about 0.01 wt % to about 30 wt % based on a total weight of the resist underlayer composition.

13. The resist underlayer composition as claimed in claim 1, wherein the composition further comprises at least one polymer selected from among an acrylic resin, an epoxy resin, a novolac-based resin, a glycoluril-based resin, and a melamine-based resin.

14. The resist underlayer composition as claimed in claim 1, wherein the composition further comprises an additive being any one of a surfactant, a thermal acid generator, a photoacid generator, a plasticizer, or a combination thereof.

15. The resist underlayer composition as claimed in claim 14, wherein the additive comprises an amount of about 0.0001 parts by weight to about 40 parts by weight based on a 100 parts by weight of the resist underlayer composition.

16. The resist underlayer composition as claimed in claim 14, wherein the additive comprises the thermal acid generator comprising at least one selected from among p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carbonic acid, benzointosylate, 2-nitrobenzyltosylate, and a combination thereof.

17. A method comprising:
forming an etching target layer on a substrate;
forming a resist underlayer on the etching target layer by applying the resist underlayer composition as claimed in claim 1;
forming a photoresist pattern on the resist underlayer; and
sequentially etching the resist underlayer and the etching target layer using the photoresist pattern as an etching mask,
wherein the method is a method of forming a photoresist pattern.

18. The method as claimed in claim 17, wherein the method comprises a first baking process having a temperature of about 100° C. to about 500° C.

19. The method as claimed in claim 17, wherein the method comprises use of a light source having a wavelength of about 5 nanometer (nm) to about 500 nm.

20. The method as claimed in claim 17, wherein the resist underlayer has a thickness of about 10 angstrom (Å) to about 300 Å.
